(19) United States
(12) Patent Application Publication
(10) Pub. No.: US 2023/0387285 A1
(43) Pub. Date: Nov. 30, 2023

(54) NITRIDE SEMICONDUCTOR DEVICE AND METHOD FOR MANUFACTURING NITRIDE SEMICONDUCTOR DEVICE

(71) Applicant: ROHM CO., LTD., Kyoto-shi (JP)

(72) Inventor: Kentaro CHIKAMATSU, Kyoto-shi (JP)

(73) Assignee: ROHM CO., LTD., Kyoto-shi (JP)

(21) Appl. No.: 18/364,479

(22) Filed: Aug. 3, 2023

Related U.S. Application Data
(63) Continuation of application No. PCT/JP2021/046551, filed on Dec. 16, 2021.

(30) Foreign Application Priority Data
Feb. 10, 2021 (JP) 2021-020035

(51) Int. Cl. H01L 29/778; H01L 29/66; H01L 29/20; H01L 29/40

(52) U.S. Cl. CPC H01L 29/7786; H01L 29/66462; H01L 29/2003; H01L 29/402

(57) ABSTRACT

A nitride semiconductor device includes an electron transit layer, an electron supply layer, a gate layer, a gate electrode, an insulation layer covering the electron supply layer, the gate layer, and the gate electrode and including a first opening and a second opening, a source electrode, and a drain electrode. The source electrode includes a source field plate covering the insulation layer and including an end located between the second opening and the gate layer in plan view. The insulation layer includes a first insulation layer part and a second insulation layer part. The first insulation layer part is disposed on the electron supply layer in contact with the drain electrode and has a first thickness. The second insulation layer part is disposed on the gate electrode in contact with the source field plate and has a second thickness. The second thickness is greater than the first thickness.

### CROSS-REFERENCE TO RELATED APPLICATIONS

This is a continuation application (CA) of PCT Application No. PCT/JP2021/046551, filed on Dec. 16, 2021, which claims priority to Japanese Patent Application No. 2021-020035, filed on Feb. 10, 2021, the entire contents of each of which are incorporated herein by reference.

### BACKGROUND

### 1. Field

The following description relates to a nitride semiconductor device and a method for manufacturing a nitride semiconductor device.

### 2. Description of Related Art

In recent years, a high electron mobility transistor (hereafter referred to as HEMT) that uses a nitride semiconductor as the main material of an active region has been developed and applied to a power device. The nitride semiconductor is a semiconductor that includes nitrogen as a group V element in a group III-V semiconductor. As compared to a typical silicon carbide (SiC) power device, a power device that uses a nitride semiconductor is recognized as a device having a low on-resistance property, which is similar to the SiC power device, and capable of operating at higher speeds and higher frequencies than the SiC power device.

Japanese Laid-Open Patent Publication No. 2017-73506 discloses an example of a HEMT including a gate portion that includes a GaN layer (p-type GaN layer) containing an acceptor impurity and a gate electrode formed on the p-type GaN layer.

### BRIEF DESCRIPTION OF THE DRAWINGS

FIG. 1 is a schematic cross-sectional view showing an exemplary nitride semiconductor device of a first embodiment.

FIG. 2 is a schematic plan view showing an exemplary pattern formed in the nitride semiconductor device shown in FIG. 1.

FIG. 3 is a schematic cross-sectional view showing an exemplary step for manufacturing the nitride semiconductor device shown in FIG. 1.

FIG. 4 is a schematic cross-sectional view showing a manufacturing step subsequent to FIG. 3.

FIG. 5 is a schematic cross-sectional view showing a manufacturing step subsequent to FIG. 4.

FIG. 6 is a schematic cross-sectional view showing a manufacturing step subsequent to FIG. 5.

FIG. 7 is a schematic cross-sectional view showing a manufacturing step subsequent to FIG. 6.

FIG. 8 is a graph showing the relationship between input capacitance and drain voltage of nitride semiconductor devices in test example 1 and test example 2.

FIG. 9 is a graph showing the relationship between total gate charge and gate voltage of the nitride semiconductor devices in test example 1 and test example 2.

FIG. 10 is a schematic cross-sectional view showing an exemplary nitride semiconductor device of a second embodiment.

FIG. 11 is a schematic cross-sectional view showing an exemplary nitride semiconductor device of a third embodiment.

FIG. 12 is a schematic cross-sectional view showing an exemplary step for manufacturing the nitride semiconductor device shown in FIG. 11.

FIG. 13 is a schematic cross-sectional view showing a manufacturing step subsequent to FIG. 12.

FIG. 14 is a schematic cross-sectional view showing a manufacturing step subsequent to FIG. 13.

FIG. 15 is a schematic cross-sectional view showing a manufacturing step subsequent to FIG. 14.

FIG. 16 is a schematic cross-sectional view showing a manufacturing step subsequent to FIG. 15.

FIG. 17 is a schematic cross-sectional view showing a manufacturing step subsequent to FIG. 16.

FIG. 18 is a schematic cross-sectional view showing a manufacturing step subsequent to FIG. 17.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Embodiments of a nitride semiconductor device according to the present disclosure will be described below with reference to the drawings.

### First Embodiment

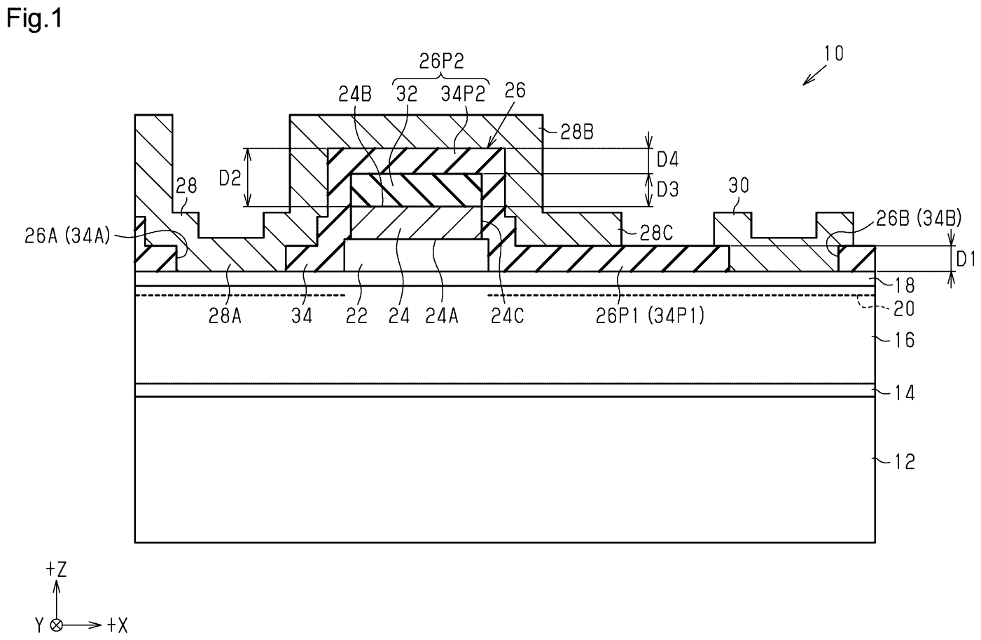

FIG. 1 is a schematic cross-sectional view showing an exemplary nitride semiconductor device 10 of a first embodiment. The term “plan view” used in the present disclosure refers to a view of the nitride semiconductor device 10 in the Z-axis direction when the XYZ-axes are orthogonal to each other as shown in FIG. 1. In the nitride semiconductor device 10 shown in FIG. 1, the +Z direction defines the upper side, and the −Z direction defines the lower side. The +X direction defines the right, and the −X direction defines the left. Unless otherwise specified, “plan view” refers to a view of the nitride semiconductor device 10 taken from above along the Z-axis.

The nitride semiconductor device 10 is a high electron mobility transistor (HEMT) that uses a nitride semiconductor. The nitride semiconductor device 10 includes a substrate 12, a buffer layer 14 formed on the substrate 12, an electron transit layer 16 formed on the buffer layer 14, and an electron supply layer 18 formed on the electron transit layer 16.

In an example, a silicon (Si) substrate is used as the substrate 12. Alternatively, a silicon carbide (SiC) substrate, a gallium nitride (GaN) substrate, or a sapphire substrate may be used instead of the Si substrate. The thickness of the substrate 12 may be, for example, greater than or equal to 200 μm and less than or equal to 1500 μm. The term “thickness” in the following description refers to a dimension extending in the z-direction shown in FIG. 1 unless otherwise specifically described.

The buffer layer 14 may be disposed between the substrate 12 and the electron transit layer 16 and may be formed of any material that reduces the lattice mismatching between the substrate 12 and the electron transit layer 16. The buffer layer 14 may include one or more nitride semiconductor layers, for example, at least one of an aluminum nitride (AlN) layer, an aluminum gallium nitride (AlGaN) layer, and a graded AlGaN layer including a different aluminum (Al) composition. In an example, the buffer layer 14 may be composed of a single film of AlN, a single film of AlGaN, a film having a superlattice structure of AlGaN/GaN, a film having a superlattice structure of AlN/AlGaN, or a film having a superlattice structure of AlN/GaN.

In an example, the buffer layer 14 may include a first buffer layer, which is an AlN layer formed on the substrate 12, and a second buffer layer, which is an AlGaN formed on the AlN layer. In an example, the first buffer layer may be an AlN layer having a thickness of 200 nm. In an example, the second buffer layer may be an AlGaN layer having a thickness of 100 nm. To inhibit current leakage from the buffer layer 14, a portion of the buffer layer 14 may be doped with an impurity so that the buffer layer 14 excluding an outer layer region is semi-insulating. In this case, the impurity is, for example, carbon (C) or iron (Fe). The concentration of the impurity may be, for example, greater than or equal to 4×10¹⁶ cm⁻³.

The electron transit layer 16 is composed of a nitride semiconductor and may be, for example, a GaN layer. The electron transit layer 16 may have a thickness that is, for example, greater than or equal to 0.5 μm and less than or equal to 2 μm. To inhibit current leakage from the electron transit layer 16, a portion of the electron transit layer 16 may be doped with an impurity so that the electron transit layer 16 excluding an outer layer region is semi-insulating. In this case, the impurity is, for example, C. The concentration of the impurity is, for example, greater than or equal to 4×10¹⁶ cm⁻³. More specifically, the electron transit layer 16 may include GaN layers having different impurity concentrations, for example, a C-doped GaN layer and a non-doped GaN layer. In this case, the C-doped GaN layer may be formed on the buffer layer 14 and have a thickness of greater than or equal to 0.5 μm and less than or equal to 2 μm. The C concentration in the C-doped GaN layer may be greater than or equal to 5×10¹⁷ cm⁻³ and less than or equal to 5×10¹⁹ cm⁻³. The non-doped GaN layer may be formed on the C-doped GaN layer and have a thickness of greater than or equal to 0.05 μm and less than or equal to 0.3 μm. The non-doped GaN layer is in contact with the electron supply layer 18. In an example, the electron transit layer 16 includes a non-doped GaN layer having a thickness of 0.1 μm and a C-doped GaN layer having a thickness of 0.911 m. The concentration of C in the C-doped GaN layer is approximately 1×10¹⁸ cm⁻³.

The electron supply layer 18 is composed of a nitride semiconductor having a band gap that is larger than that of the electron transit layer 16 and may be, for example, an AlGaN layer. In the nitride semiconductor, the band gap becomes larger as the composition of Al is increased. Therefore, the electron supply layer 18, which is an AlGaN layer, has a larger band gap than the electron transit layer 16, which is a GaN layer. In an example, the electron supply layer 18 is composed of AlₓGa₁₋ₓN, where 0<x<0.4, and more preferably, 0.1<x<0.3. The electron supply layer 18 may have a thickness of, for example, greater than or equal to 5 nm and less than or equal to 20 nm.

The electron transit layer 16 and the electron supply layer 18 have different lattice constants in a bulk region. This results in the lattice mismatching between the electron transit layer 16 and the electron supply layer 18. In the vicinity of the heterojunction interface between the electron transit layer 16 and the electron supply layer 18, the energy level in the conduction band of the electron transit layer 16 is lower than the Fermi level due to spontaneous polarization of the electron transit layer 16 and the electron supply layer 18 and piezoelectric polarization caused by compressive stress received by a heterojunction of the electron supply layer 18. As a result, at a location close to the heterojunction interface between the electron transit layer 16 and the electron supply layer 18 (for example, approximately a few nanometers away from the interface), two-dimensional electron gas 20 (2DEG) spreads in the electron transit layer 16.

The nitride semiconductor device 10 further includes a gate layer 22 formed on the electron supply layer 18 and a gate electrode 24 formed on the gate layer 22.

The gate layer 22, formed on the electron supply layer 18, is formed from a nitride semiconductor having a band gap that is smaller than that of the electron supply layer 18 and including an acceptor impurity. The gate layer 22 may be formed of any material having a band gap that is smaller than that of the electron supply layer 18, which is, for example, an AlGaN layer. In an example, the gate layer 22 is a GaN layer (p-type GaN layer) doped with an acceptor impurity. The acceptor impurity may include at least one of zinc (Zn), magnesium (Mg), and carbon (C). The maximum concentration of the acceptor impurity in the gate layer 22 is, for example, greater than or equal to 1×10¹⁸ cm⁻³ and less than or equal to 1×10²⁰ cm⁻³. The gate layer 22 may have, for example, a thickness of greater than or equal to 80 nm and less than or equal to 150 nm and have a cross section that is rectangular, trapezoidal, or, ridged.

As described above, the acceptor impurity included in the gate layer 22 increases the energy levels of the electron transit layer 16 and the electron supply layer 18. As a result, in a region immediately below the gate layer 22, the energy level of the conduction band of the electron transit layer 16 in the vicinity of the heterojunction interface between the electron transit layer 16 and the electron supply layer 18 is substantially equal to or greater than the Fermi level. Therefore, when no voltage is applied to the gate electrode 24, that is, in the zero bias state, the 2DEG 20 is not formed in the electron transit layer 16 in the region immediately below the gate layer 22. On the other hand, in a region other than the region immediately below the gate layer 22, the 2DEG 20 is formed in the electron transit layer 16.

As described above, when the gate layer 22 is doped with the acceptor impurity, the 2DEG 20 is depleted in the region immediately below the gate layer 22. As a result, the nitride semiconductor device 10 performs a normally-off operation. When an appropriate on-voltage is applied to the gate electrode 24, the 2DEG 20 forms a channel in the electron transit layer 16 in the region immediately below the gate electrode 24. This electrically connects the source and the drain.

The gate electrode 24 is formed on the gate layer 22. The gate electrode 24 includes a lower surface 24A (first surface) in contact with the gate layer 22, an upper surface 24B (second surface) opposite to the lower surface 24A, and a side surface 24C (third surface) extending between the lower surface 24A and the upper surface 24B. The gate electrode 24 is composed of one or more metal layers, an example of which is a titanium nitride (TiN) layer. Alternatively, the gate electrode 24 may include a first metal layer composed of Ti and a second metal layer composed of TiN and disposed on the first metal layer. The gate electrode 24 may have a thickness that is, for example, greater than or equal to 50 nm and less than or equal to 200 nm. The gate electrode 24 may form a Schottky junction with the gate layer 22.

The nitride semiconductor device 10 further includes an insulation layer 26, a source electrode 28, and a drain electrode 30. The insulation layer 26 covers the electron supply layer 18, the gate layer 22, and the gate electrode 24 and includes a first opening 26A and a second opening 26B. The first opening 26A and the second opening 26B are separated from the gate layer 22. The gate layer 22 is located between the first opening 26A and the second opening 26B. More specifically, the gate layer 22 is located closer to the first opening 26A than the second opening 26B between the first opening 26A and the second opening 26B. The source electrode 28 is in contact with the electron supply layer 18 through the first opening 26A. The drain electrode 30 is in contact with the electron supply layer 18 through the second opening 26B.

The source electrode 28 and the drain electrode 30 are composed of one or more metal layers (for example, Ti, Al, TiN). The source electrode 28 and the drain electrode 30 are each in ohmic contact with the electron supply layer 18 through the first opening 26A and the second opening 26B.

The source electrode 28 includes a source contact 28A and a source field plate 28B continuous with the source contact 28A. The source contact 28A corresponds to a portion of the source electrode 28 filling the first opening 26A. The source field plate 28B is formed integrally with the source contact 28A. The source field plate 28B covers the insulation layer 26 and includes an end 28C located between the second opening 26B and the gate layer 22 in plan view. Thus, the source field plate 28B is separated from the drain electrode 30, which is formed in the second opening 26B. The source field plate 28B extends from the source contact 28A to the end 28C along the surface of the insulation layer 26 toward the drain electrode 30. The insulation layer 26 covers the upper surface of the electron supply layer 18, the side surface and the upper surface of the gate layer 22, the side surface 24C and the upper surface 24B of the gate electrode 24. Therefore, the source field plate 28B, which extends along the surface of the insulation layer 26, has a non-flat surface. When no gate voltage is applied to the gate electrode 24, that is, in the zero bias state, the source field plate 28B reduces the concentration of electric field in the vicinity of the end of the gate electrode 24.

The insulation layer 26 includes a first insulation layer part 26P1 having a first thickness D1 and a second insulation layer part 26P2 having a second thickness D2.

The first insulation layer part 26P1 is disposed on the electron supply layer 18 in contact with the drain electrode 30. The first insulation layer part 26P1 corresponds to a part of the insulation layer 26 having the first thickness D1, which is a constant thickness, between the gate layer 22 and the drain electrode 30. The first insulation layer part 26P1 is partially covered by the source field plate 28B. More specifically, a portion of the first insulation layer part 26P1 located toward the gate layer 22 is covered by the source field plate 28B. Therefore, the end 28C of the source field plate 28B is located on the first insulation layer part 26P1. In other words, the first insulation layer part 26P1 is a part of the insulation layer 26 on which the end 28C of the source field plate 28B is disposed.

The second insulation layer part 26P2 is disposed on the gate electrode 24 in contact with the source field plate 28B. The second insulation layer part 26P2 corresponds to a part of the insulation layer 26 disposed on the gate electrode 24 and having the second thickness D2, which is a constant thickness. The second insulation layer part 26P2 is entirely covered by the source field plate 28B.

The second thickness D2 of the second insulation layer part 26P2 is greater than the first thickness D1 of the first insulation layer part 26P1. The second thickness D2 may be greater than or equal to 1.2 times the first thickness D1 and less than or equal to 5.0 times the first thickness D1. The first thickness D1 may be greater than or equal to 50 nm and less than or equal to 200 nm. The second thickness D2 may be greater than or equal to 100 nm and less than or equal to 400 nm.

The first thickness D1 is a thickness of the insulation layer 26 where the end 28C of the source field plate 28B is located in plan view. In other words, the first thickness D1 is a distance between the electron supply layer 18 and the source electrode 28 where the end 28C of the source field plate 28B is located in plan view. The second thickness D2 is a distance between the gate electrode 24 and the source electrode 28 in a region of the gate electrode 24 in plan view. Thus, an increase in the second thickness D2 decreases the gate-source capacitance C_{gs}.

Theoretically, as the second thickness D2 is increased, the gate-source capacitance C_{gs} can be decreased more. However, when the nitride semiconductor device 10 is used to form a circuit, if the ratio (input capacitance Cᵢₛₛ/feedback capacitance Cᵣₛₛ) of input capacitance Cᵢₛₛ (=gate-drain capacitance C_{gd}+gate-source capacitance C_{gs}) to feedback capacitance Cᵣₛₛ (=gate-drain capacitance C_{gd}) becomes smaller than a certain value (for example, 100), a self-turn-on phenomenon may occur, resulting in shoot-through current. Therefore, the second thickness D2 may be set in a range so that the ratio of input capacitance Cᵢₛₛ to feedback capacitance Cᵣₛₛ will not become below a value (for example, 150) determined in accordance with the circuit design.

The insulation layer 26 includes a spacer layer 32, formed on the gate electrode 24, and a passivation layer 34 covering the electron supply layer 18, the gate layer 22, the gate electrode 24, and the spacer layer 32. The passivation layer 34 includes a first opening 34A and a second opening 34B.

The first opening 34A and the second opening 34B of the passivation layer 34 respectively correspond to the first opening 26A and the second opening 26B of the insulation layer 26. The first insulation layer part 26P1 is formed of the passivation layer 34. The second insulation layer part 26P2 is formed of the spacer layer 32 and the passivation layer 34. For the sake of brevity, the part of the passivation layer 34 forming the first insulation layer part 26P1 is referred to as a first passivation layer part 34P1. Also, a part of the passivation layer 34 disposed on the spacer layer 32 forming the second insulation layer part 26P2 together with the spacer layer 32 is referred to as a second passivation layer part 34P2.

The spacer layer 32 may be composed of, for example, one of silicon nitride (SiN), silicon dioxide (SiO₂), silicon oxynitride (SiON), alumina (Al₂O₃), AlN, and aluminum oxynitride (AlON). In an example, the spacer layer 32 is composed of SiO₂. As shown in FIG. 1, the spacer layer 32 has a third thickness D3. The spacer layer 32 disposed on the gate electrode 24 increases the distance between the gate electrode 24 and the source electrode 28 in the z-direction. This decreases the gate-source capacitance C_{gs}.

The passivation layer 34 may be composed of, for example, one of SiN, SiO₂, SiON, Al₂O₃, AlN, and AlON. In an example, the passivation layer 34 is composed of SiN. The passivation layer 34 may serve as a protection film.

As shown in FIG. 1, the passivation layer 34 has the first thickness D1 in the first insulation layer part 26P1 and a fourth thickness D4 in the second insulation layer part 26P2. In other words, the first passivation layer part 34P1 has the first thickness D1. The second passivation layer part 34P2 has the fourth thickness D4. In the present embodiment, the first thickness D1 is substantially equal to the fourth thickness D4. In this specification, “substantially equal” means that the difference is within a manufacturing variation range (for example, 20%).

As described above, in the second insulation layer part 26P2, the spacer layer 32 has the third thickness D3, and the passivation layer 34 has the fourth thickness D4. Thus, the second thickness D2 of the second insulation layer part 26P2 is the sum of the third thickness D3 and the fourth thickness D4. In addition to the passivation layer 34, the spacer layer 32 increases the second thickness D2. This decreases the gate-source capacitance C_{gs}.

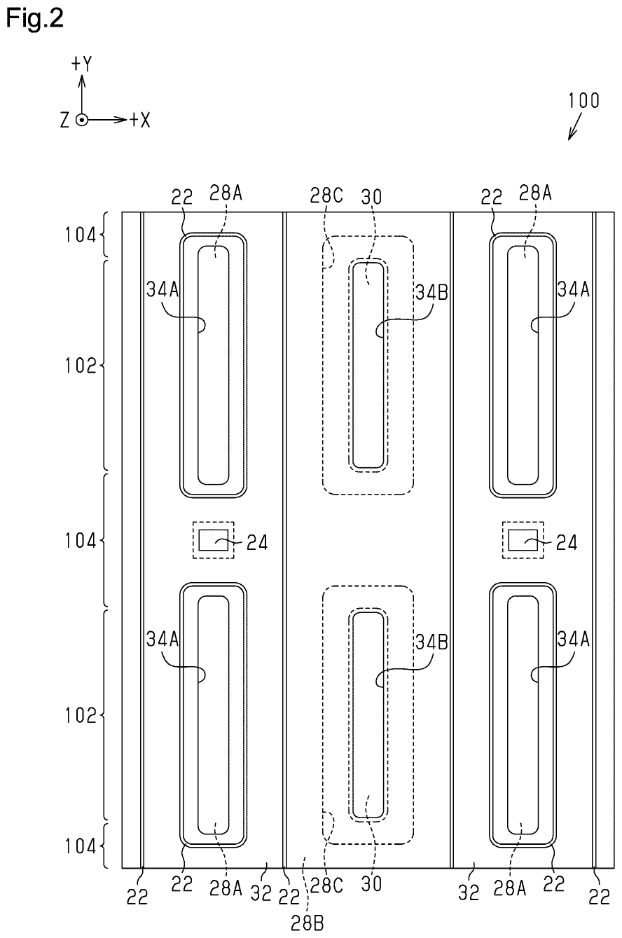

FIG. 2 is a schematic plan view showing an exemplary pattern 100 formed in the nitride semiconductor device 10 shown in FIG. 1. To facilitate understanding, in FIG. 2, the same reference characters are given to those components that are the same as the corresponding components shown in FIG. 1. Also, in FIG. 2, the source electrode 28, the drain electrode 30, and the passivation layer 34 are transparently shown so that components of layers underneath (for example, the spacer layer 32 and the gate layer 22) are visible. The source electrode 28 and the drain electrode 30 are shown by broken lines indicating only the outer edges. In the passivation layer 34, only the first opening 34A and the second opening 34B (corresponding to the first opening 26A and the second opening 26B of the insulation layer 26) are shown.

As shown in FIG. 2, the pattern 100 includes active regions 102 that contribute to operation of the transistor and inactive regions 104 that do not contribute to operation of the transistor. The active region 102 refers to a region in which, when voltage is applied to the gate electrode 24, current flows between the source and the drain.

In the active region 102, multiple (in the example shown in FIG. 2, four) nitride semiconductor devices are continuously formed in an X-axis direction. Each nitride semiconductor device shown in FIG. 2 corresponds to the nitride semiconductor device 10 shown in FIG. 1. More specifically, the cross-sectional view shown in FIG. 1 corresponds to a cross-sectional view of the pattern 100 in the active region 102 enlarging a portion including one nitride semiconductor device (including gate electrode, and source electrode and drain electrode associated with the gate electrode). In the active region 102, the source field plate 28B of the source electrode 28 includes the end 28C located between the second opening 34B (corresponding to the second opening 26B) and the gate layer 22. The drain electrode 30 is formed in the second opening 34B. The drain electrode 30 is not formed in the inactive region 104.

As shown in FIG. 2, the gate layer 22, the spacer layer 32, and the source electrode 28 are continuously formed over the active region 102 and the inactive region 104 in the Y-axis direction.

An example of a method for manufacturing the nitride semiconductor device 10 shown in FIG. 1 will be described.

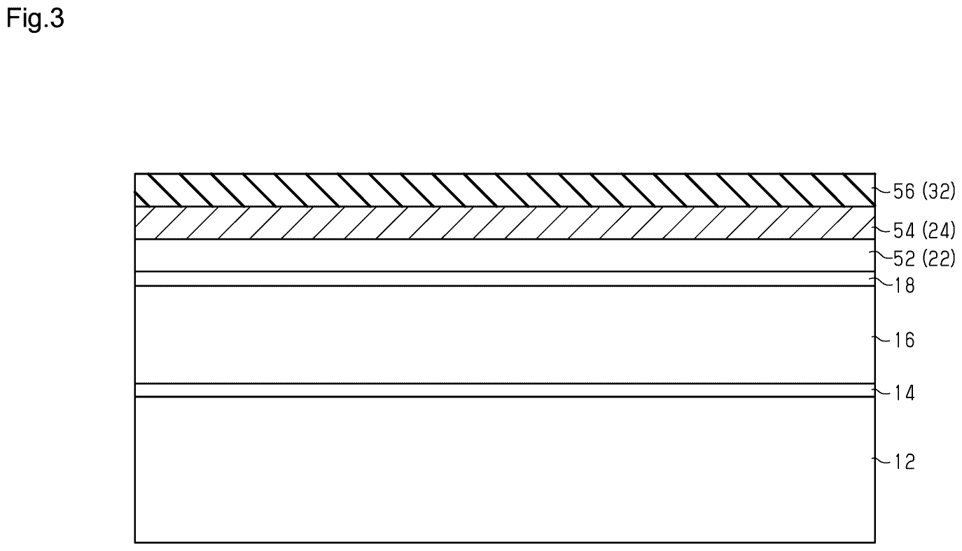

FIGS. 3 to 7 are schematic cross-sectional views showing exemplary manufacturing steps of the nitride semiconductor device 10. To facilitate understanding, in FIGS. 3 to 7, the same reference characters are given to those components that are the same as the corresponding components shown in FIG. 1. Elements that will ultimately become the elements of the nitride semiconductor device 10 are denoted by the corresponding reference characters shown in FIG. 1 in parentheses.

A method for manufacturing the nitride semiconductor device 10 includes forming the electron transit layer 16 composed of a nitride semiconductor, forming the electron supply layer 18 on the electron transit layer 16, the electron supply layer 18 being composed of a nitride semiconductor having a band gap that is larger than that of the electron transit layer 16, forming the gate layer 22 on the electron supply layer 18, the gate layer 22 composed of a nitride semiconductor including an acceptor impurity, forming the gate electrode 24 on the gate layer 22, and forming the insulation layer 26 (refer to FIG. 1) that covers the electron supply layer 18, the gate layer 22, and the gate electrode 24 and includes the first opening 26A and the second opening 26B. The forming the insulation layer 26 includes forming the spacer layer 32 on the gate electrode 24 and forming the passivation layer 34 that covers the electron supply layer 18, the gate layer 22, the gate electrode 24, and the spacer layer 32 and includes the first opening 34A and the second opening 34B. The first opening 34A and the second opening 34B of the passivation layer 34 respectively correspond to the first opening 26A and the second opening 26B of the insulation layer 26.

As shown in FIG. 3, for example, the buffer layer 14, the electron transit layer 16, the electron supply layer 18, a nitride semiconductor layer 52, a metal layer 54, and a spacer insulation layer 56 are sequentially formed on the substrate 12, which is a Si substrate.

Metal organic chemical vapor deposition (MOCVD) may be used to epitaxially grow the buffer layer 14, the electron transit layer 16, the electron supply layer 18, and the nitride semiconductor layer 52.

Although not shown in detail, in an example, the buffer layer 14 is multilayer. An AlN layer (the first buffer layer) is formed on the substrate 12, and then a graded AlGaN layer (the second buffer layer) is formed on the AlN layer. The graded AlGaN layer is formed, for example, by stacking three AlGaN layers having Al compositions of 75%, 50%, and 25% in the order from the side of the AlN layer.

A GaN layer is formed on the buffer layer 14 as the electron transit layer 16. An AlGaN layer is formed on the electron transit layer 16 as the electron supply layer 18. Thus, the electron supply layer 18 has a band gap that is larger than that of the electron transit layer 16. Then, a GaN layer including an acceptor impurity is formed on the electron supply layer 18 as the nitride semiconductor layer 52.

The buffer layer 14, the electron transit layer 16, the electron supply layer 18, and the nitride semiconductor layer 52 are composed of nitride semiconductors having lattice constants relatively close to each other. This allows for sequential epitaxial growth of the layers.

Subsequently, the metal layer 54 is formed on the nitride semiconductor layer 52. In an example, the metal layer 54 is a TiN layer formed through sputtering. Then, the spacer insulation layer 56 is formed on the metal layer 54. In an example, the spacer insulation layer 56 is a SiO₂ layer formed by plasma CVD.

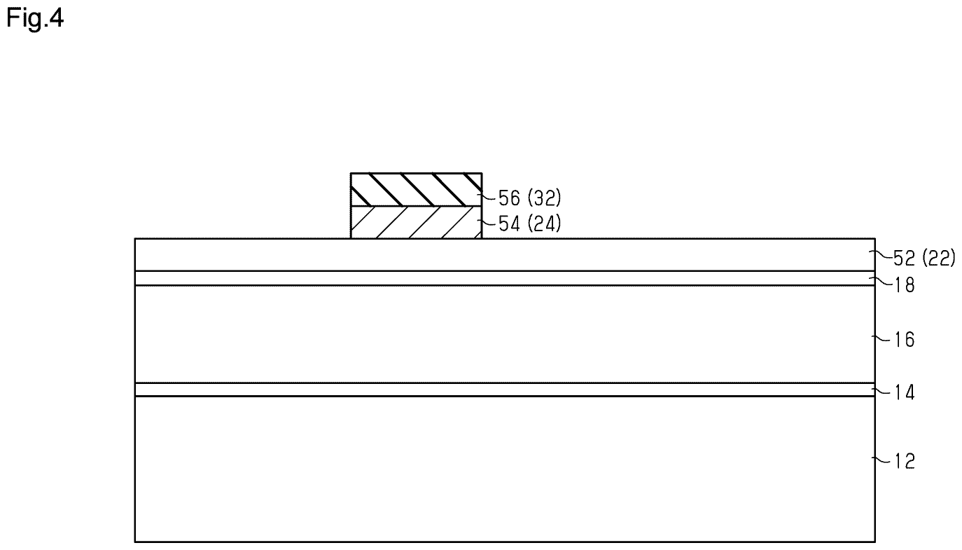

FIG. 4 is a schematic cross-sectional view showing a manufacturing step subsequent to FIG. 3. As shown in FIG. 4, the metal layer 54 and the spacer insulation layer 56 are selectively removed by lithography and etching to form the gate electrode 24 and the spacer layer 32.

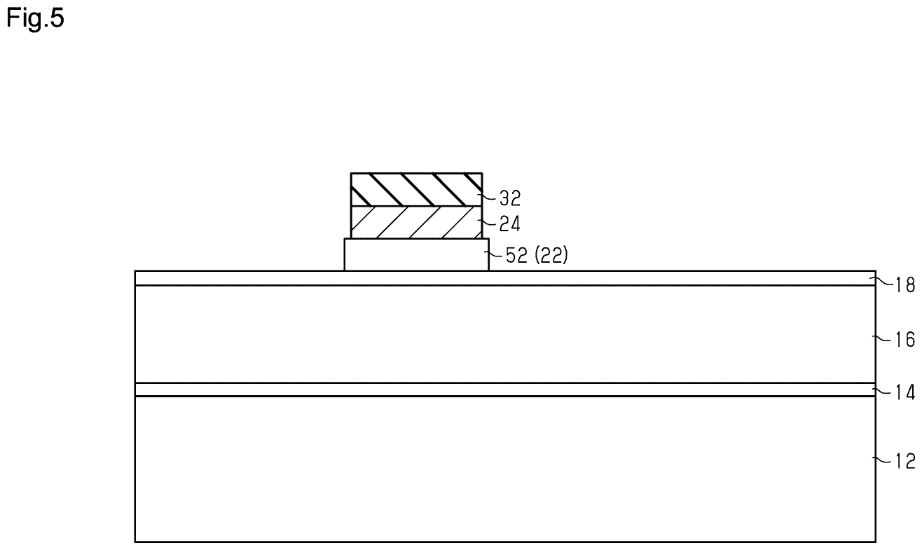

FIG. 5 is a schematic cross-sectional view showing a manufacturing step subsequent to FIG. 4. As shown in FIG. 5, the nitride semiconductor layer 52 is selectively removed by lithography and etching to form the gate layer 22. As a result, a stacking structure including the gate layer 22, the gate electrode 24 formed on the gate layer 22, and the spacer layer 32 formed on the gate electrode 24 is formed on a portion of the upper surface of the electron supply layer 18.

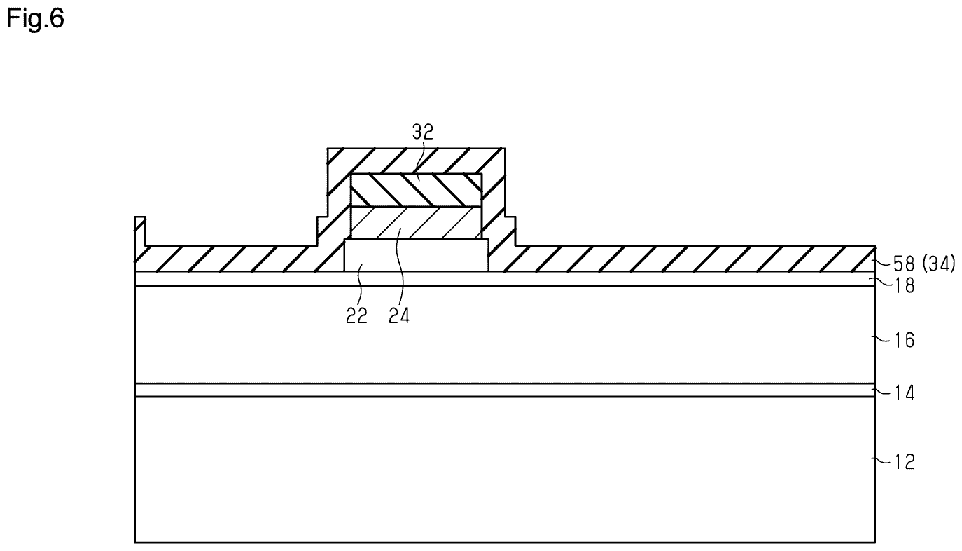

FIG. 6 is a schematic cross-sectional view showing a manufacturing step subsequent to FIG. 5. As shown in FIG. 6, a passivation insulation layer 58 is formed to cover the entirety of exposed surfaces of the electron supply layer 18, the gate layer 22, the gate electrode 24, and the spacer layer 32. In an example, the passivation insulation layer 58 is a SiN layer formed by low-pressure chemical vapor deposition (LPCVD). The passivation insulation layer 58 may have a thickness that is greater than or equal to 50 nm and less than or equal to 200 nm.

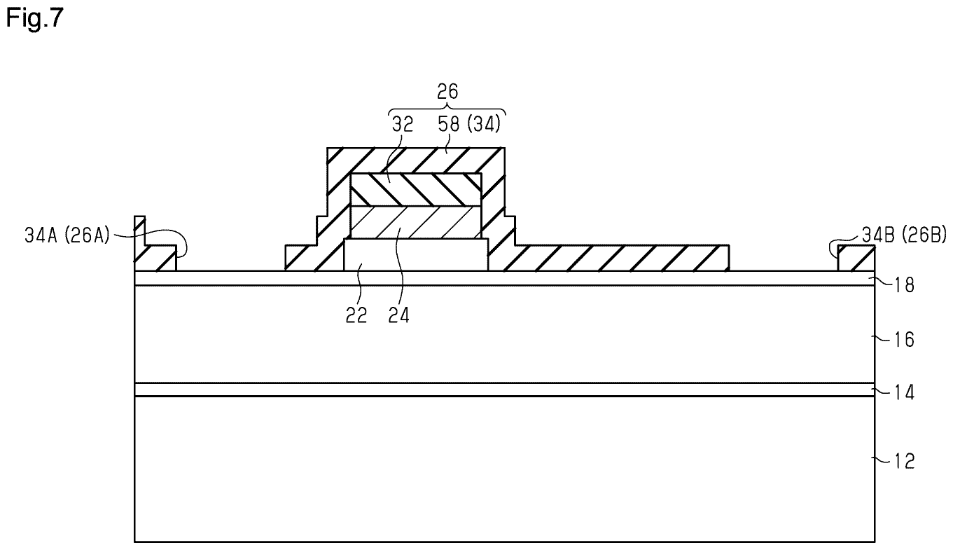

FIG. 7 is a schematic cross-sectional view showing a manufacturing step subsequent to FIG. 6. As shown in FIG. 7, the passivation insulation layer 58 is selectively removed by lithography and etching to form the passivation layer 34 including the first opening 34A and the second opening 34B. More specifically, the passivation insulation layer 58 is patterned so that the gate layer 22 is disposed between the first opening 34A and the second opening 34B. The passivation layer 34 covers the electron supply layer 18, the gate layer 22, the gate electrode 24, and the spacer layer 32 and includes the first opening 34A and the second opening 34B. The insulation layer 26 is defined to include the spacer layer 32 and the passivation layer 34. The first opening 34A and the second opening 34B of the passivation layer 34 respectively correspond to the first opening 26A and the second opening 26B of the insulation layer 26.

The method for manufacturing the nitride semiconductor device 10 further includes forming the source electrode 28 (refer to FIG. 1), which is in contact with the electron supply layer 18 through the first opening 26A, and forming the drain electrode 30 (refer to FIG. 1), which is in contact with the electron supply layer 18 through the second opening 26B.

In a manufacturing step subsequent to the step shown in FIG. 7, a metal layer is formed to fill the first opening 26A and the second opening 26B and cover the entirety of exposed surfaces of the passivation layer 34 (the insulation layer 26). The metal layer (e.g., one or more metal layers including Ti, Al, TiN, and the like) is patterned by lithography and etching to form the source electrode 28 and the drain electrode 30. The source electrode 28 includes the source field plate 28B covering the insulation layer 26. The source field plate 28B includes the end 28C located between the second opening 26B and the gate layer 22 in plan view. This obtains the nitride semiconductor device 10 shown in FIG. 1.

The operation of the nitride semiconductor device 10 of the present embodiment will be described below.

In the nitride semiconductor device 10, the insulation layer 26 includes the first insulation layer part 26P1 having the first thickness D1 and the second insulation layer part 26P2 having the second thickness D2 that is greater than the first thickness D1. The second thickness D2 corresponds to the distance between the gate electrode 24 and the source electrode 28 in a region of the gate electrode 24 in plan view. In this structure, the distance between the gate electrode 24 and the source electrode 28 in the Z-direction is increased as compared to a structure in which the second thickness D2 is equal to the first thickness D1. Thus, the gate-source capacitance C_{gs} of the nitride semiconductor device 10 is decreased.

More specifically, in the present embodiment, the insulation layer 26 includes the spacer layer 32 in addition to the passivation layer 34. Therefore, in the present embodiment, the distance between the gate electrode 24 and the source electrode 28 in the Z-direction is increased by the thickness of the spacer layer 32 (the third thickness D3) from a structure in which the spacer layer 32 is not disposed on the gate electrode 24. Thus, the gate-source capacitance C_{gs} of the nitride semiconductor device 10 is decreased.

The operation characteristics of the nitride semiconductor device 10 will now be described using test example 1 and test example 2.

In test example 1 of a nitride semiconductor device, the second thickness D2 is approximate 2.0 times the first thickness D1. In test example 2 of a nitride semiconductor device, the second thickness D2 is substantially equal to the first thickness D1. The nitride semiconductor devices of test example 1 and text example 2 have the same structure except for the second thickness D2. The nitride semiconductor device of test example 1, in which the second thickness D2 is greater than the first thickness D1, may correspond to the nitride semiconductor device 10.

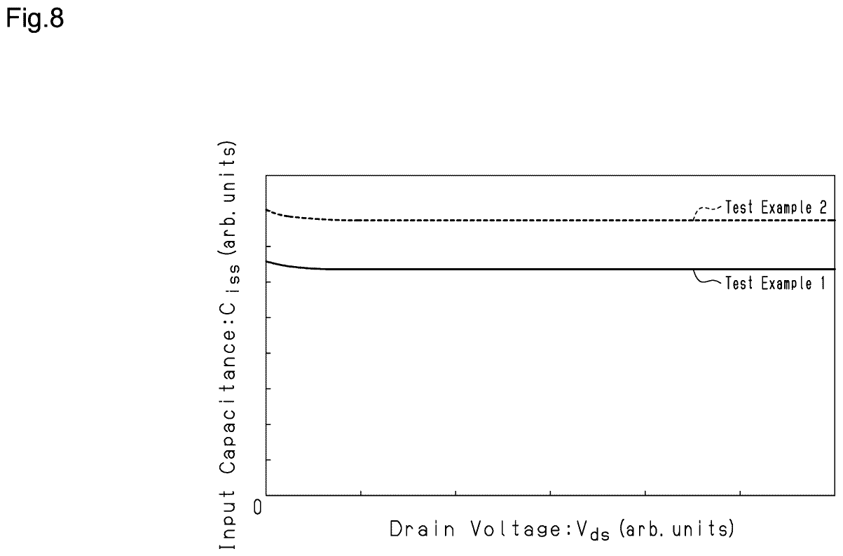

FIG. 8 is a graph showing the relationship between input capacitance Cᵢₛₛ and drain voltage V_{ds} of nitride semiconductor devices in test example 1 and test example 2. In the graph, the horizontal axis indicates the drain voltage V_{ds}, and the vertical axis indicates the input capacitance Cᵢₛₛ. In the graph, test example 1 is indicated by a solid line, and test example 2 is indicated by a broken line.

As shown in FIG. 8, for example, the input capacitance Cᵢₛₛ of test example 1 is decreased by approximately 18% from the input capacitance Cᵢₛₛ of test example 2 at a given drain voltage V_{ds}. The input capacitance Cᵢₛₛ is the sum of the gate-source capacitance C_{gs} and the gate-drain capacitance C_{gd}. This shows that an increase in the second thickness D2 from the first thickness D1 decreases the gate-source capacitance C_{gs}, thereby decreasing the input capacitance Cᵢₛₛ.

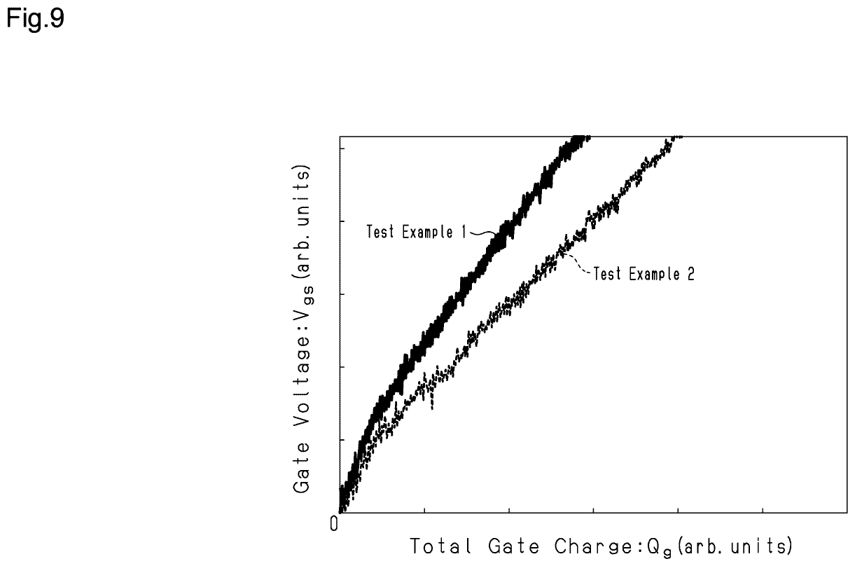

FIG. 9 is a graph showing the relationship between total gate charge Q_{g} and gate voltage V_{gs} of the nitride semiconductor devices in test example 1 and test example 2. In the graph, the horizontal axis indicates the total gate charge Q_{g}, and the vertical axis indicates the gate voltage V_{gs}. In the graph, test example 1 is indicated by a solid line, and test example 2 is indicated by a broken line.

As shown in FIG. 9, the total gate charge Q_{g} of test example 1 is decreased by approximately 30% from the total gate charge Q_{g} of test example 2 at a given gate voltage V_{gs}. This shows that when the second thickness D2 is increased from the first thickness D1, the total gate charge Q_{g} of the nitride semiconductor device is decreased.

The total gate charge Q_{g} represents an amount of charge necessary to be supplied to the gate electrode in order to activate the transistor. When the total gate charge Q_{g} is large, charging to the amount necessary to activate the transistor takes a longer time. This increases switching loss. Therefore, as the total gate charge Q_{g} is decreased, switching loss will be decreased. This allows for high-speed switching.

The nitride semiconductor device 10 of the first embodiment has the following advantages.
(1-1) The insulation layer 26 includes the first insulation layer part 26P1 having the first thickness D1 and the second insulation layer part 26P2 having the second thickness D2. The first insulation layer part 26P1 is disposed on the electron supply layer 18 in contact with the drain electrode 30. The second insulation layer part 26P2 is disposed on the gate electrode 24 in contact with the source field plate 28B. The second thickness D2 of the second insulation layer part 26P2 is greater than the first thickness D1 of the first insulation layer part 26P1.

In this structure, the distance between the gate electrode 24 and the source electrode 28 in the Z-direction is increased as compared to a structure in which the second thickness D2 is equal to the first thickness D1. This results in a decrease in the gate-source capacitance C_{gs}, thereby limiting an increase in the input capacitance Cᵢₛₛ and the total gate charge Q_{g}.
(1-2) The second thickness D2 is greater than or equal to 1.2 times the first thickness (D1) and less than or equal to 5.0 times the first thickness (D1).

In this structure, the gate-source capacitance C_{gs} is decreased by a relatively large amount. Thus, increases in the input capacitance Cᵢₛₛ and the total gate charge Q_{g}. are further effectively limited.
(1-3) The insulation layer 26 includes the spacer layer 32, formed on the gate electrode 24, and the passivation layer 34 covering the electron supply layer 18, the gate layer 22, the gate electrode 24, and the spacer layer 32. The first insulation layer part 26P1 is formed of the passivation layer 34. The second insulation layer part 26P2 is formed of the spacer layer 32 and the passivation layer 34.

In this structure, the spacer layer 32 disposed on the gate electrode 24 increases the distance between the gate electrode 24 and the source electrode 28 in the z-direction. Thus, the gate-source capacitance C_{gs} is decreased.

### Second Embodiment

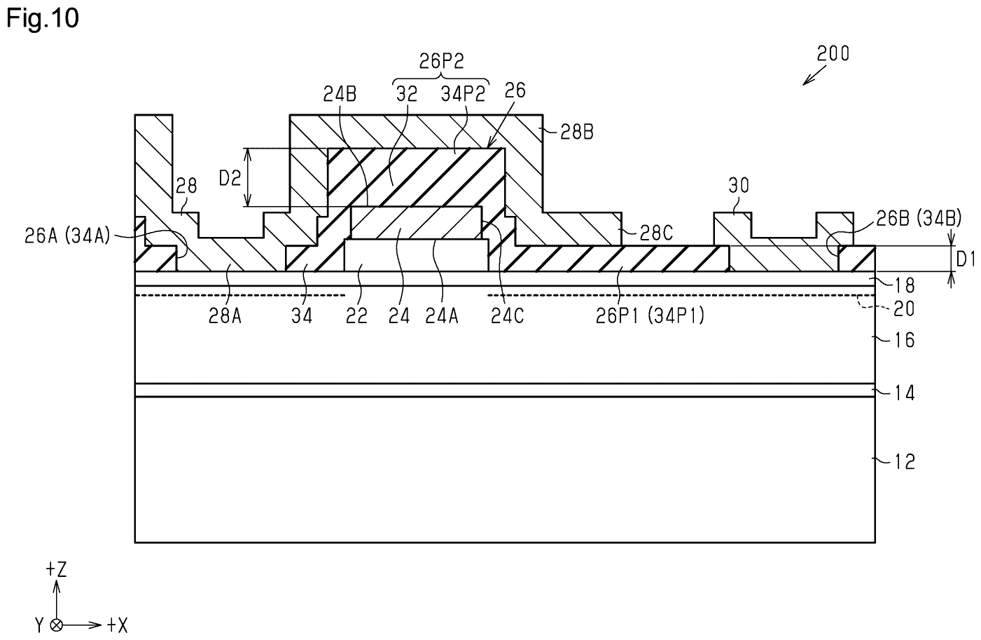

FIG. 10 is a schematic cross-sectional view showing an exemplary nitride semiconductor device 200 of a second embodiment. In FIG. 10, the same reference characters are given to those components that are the same as the corresponding components of the nitride semiconductor device 10 of the first embodiment. Such components will not be described in detail.

In a semiconductor device of a nitride semiconductor device 200, the spacer layer 32 and the passivation layer 34 are composed of the same material. In an example, each of the spacer layer 32 and the passivation layer 34 is composed of SiN. Hence, the border between the spacer layer 32 and the passivation layer 34 of the insulation layer 26 is not drawn in FIG. 10. In the nitride semiconductor device 200, an interface may, but does not necessarily have to, be formed between the spacer layer 32 and the passivation layer 34. However, there may be no visible interface formed between the spacer layer 32 and the passivation layer 34 that are composed of the same material. An exemplary pattern formed in the nitride semiconductor device 200 is similar to the pattern 100 shown in FIG. 2.

The method for manufacturing the nitride semiconductor device 200 is substantially the same as that of the nitride semiconductor device 10. In the second embodiment, each of the spacer insulation layer 56 and the passivation insulation layer 58 may be a SiN layer formed by LPCVD.

The operation characteristics of the nitride semiconductor device 200 may correspond to test example 1 shown in FIGS. 8 and 9 in the same manner as the nitride semiconductor device 10. Therefore, the increase in the second thickness D2 from the first thickness D1 decreases the gate-source capacitance C_{gs}, thereby decreasing the input capacitance Cᵢₛₛ and the total gate charge Q_{g}.

As described above, the nitride semiconductor device 200 of the second embodiment has the same advantages as the nitride semiconductor device 10 of the first embodiment.

### Third Embodiment

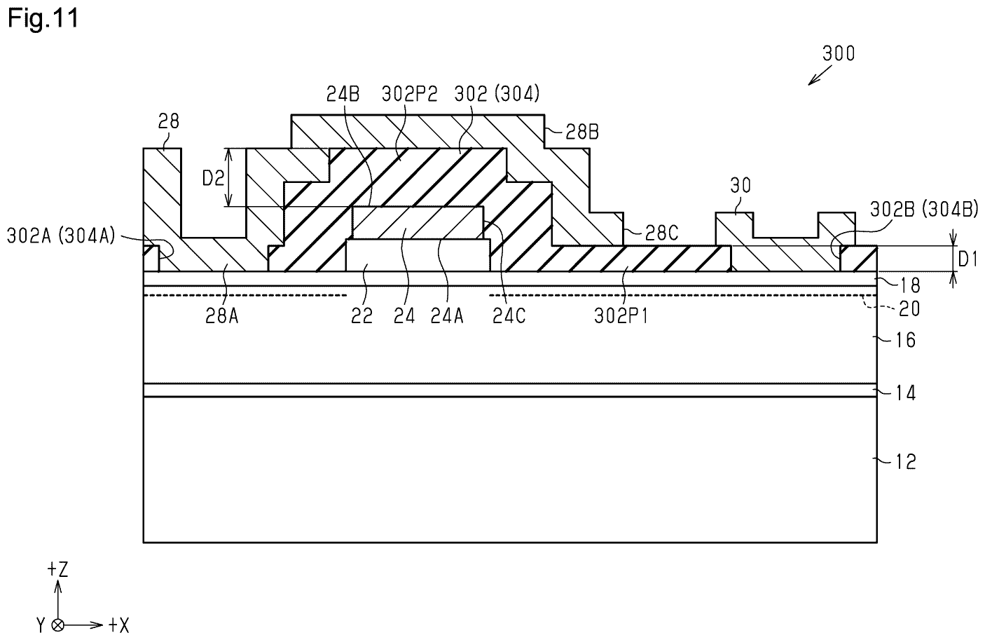

FIG. 11 is a schematic cross-sectional view showing an exemplary nitride semiconductor device 300 of a third embodiment. In FIG. 11, the same reference characters are given to those components that are the same as the corresponding components of the nitride semiconductor device 10 of the first embodiment. Such components will not be described in detail.

The nitride semiconductor device 300 of the third embodiment includes an insulation layer 302 instead of the insulation layer 26 (refer to FIG. 1). The insulation layer 302 covers the electron supply layer 18, the gate layer 22, and the gate electrode 24 and includes a first opening 302A and a second opening 302B. The first opening 302A and the second opening 302B are separated from the gate layer 22. The gate layer 22 is located between the first opening 302A and the second opening 302B. More specifically, the gate layer 22 is located closer to the first opening 302A than the second opening 302B between the first opening 302A and the second opening 302B. The source electrode 28 is in contact with the electron supply layer 18 through the first opening 302A. The drain electrode 30 is in contact with the electron supply layer 18 through the second opening 302B.

The insulation layer 302 includes a first insulation layer part 302P1 having a first thickness D1 and a second insulation layer part 302P2 having a second thickness D2.

The first insulation layer part 302P1 is disposed on the electron supply layer 18 in contact with the drain electrode 30. The first insulation layer part 302P1 corresponds to a part of the insulation layer 302 having the first thickness D1, which is a constant thickness, between the gate layer 22 and the drain electrode 30. The first insulation layer part 302P1 is partially covered by the source field plate 28B. More specifically, a portion of the first insulation layer part 302P1 located toward the gate layer 22 is covered by the source field plate 28B. Therefore, the end 28C of the source field plate 28B is located on the first insulation layer part 302P1. In other words, the first insulation layer part 302P1 is a part of the insulation layer 302 on which the end 28C of the source field plate 28B is disposed.

The second insulation layer part 302P2 is disposed on the gate electrode 24 in contact with the source field plate 28B. The second insulation layer part 302P2 corresponds to a part of the insulation layer 302 disposed on the gate electrode 24 and having the second thickness D2, which is a constant thickness. The second insulation layer part 302P2 is entirely covered by the source field plate 28B.

The second thickness D2 of the second insulation layer part 302P2 is greater than the first thickness D1 of the first insulation layer part 302P1. The second thickness D2 may be greater than or equal to 1.2 times the first thickness D1 and less than or equal to 5.0 times the first thickness D1. The first thickness D1 may be greater than or equal to 50 nm and less than or equal to 200 nm. The second thickness D2 may be greater than or equal to 100 nm and less than or equal to 400 nm.

The first thickness D1 is a thickness of the insulation layer 302 where the end 28C of the source field plate 28B is located in plan view. In other words, the first thickness D1 is a distance between the electron supply layer 18 and the source electrode 28 where the end 28C of the source field plate 28B is located in plan view. The second thickness D2 is a distance between the gate electrode 24 and the source electrode 28 in a region of the gate electrode 24 in plan view. Thus, an increase in the second thickness D2 decreases the gate-source capacitance C_{gs}. In the same manner as the first embodiment, the second thickness D2 may be set in a range so that the ratio of input capacitance Cᵢₛₛ to feedback capacitance Cᵣₛₛ will not become below a value (for example, 150) determined in accordance with the circuit design.

In the present embodiment, the insulation layer 302 is a passivation layer 304. Each of the first insulation layer part 302P1 and the second insulation layer part 302P2 is formed of the passivation layer 304. That is, the insulation layer 302 is formed of only the passivation layer 304.

The nitride semiconductor device 300 differs from the nitride semiconductor device 10 of the first embodiment in that the nitride semiconductor device 300 does not include the spacer layer 32. In the first embodiment, the second insulation layer part 26P2 is formed of the spacer layer 32 and the passivation layer 34. In the third embodiment, the second insulation layer part 302P2 is formed of the passivation layer 304.

The insulation layer 302 (the passivation layer 304) may be composed of, for example, one of SiN, SiO₂, SiON, Al₂O₃, AlN, and AlON. In an example, the insulation layer 302 is composed of SiN. The insulation layer 302 may serve as a protection film.

An exemplary pattern formed in the nitride semiconductor device 300 is similar to the pattern 100 shown in FIG. 2. In the pattern formed in the nitride semiconductor device 300, the insulation layer 302 (the passivation layer 304) is used in lieu of the insulation layer 26 (the passivation layer 34) of the pattern 100.

An example of a method for manufacturing the nitride semiconductor device 300 shown in FIG. 11 will be described.

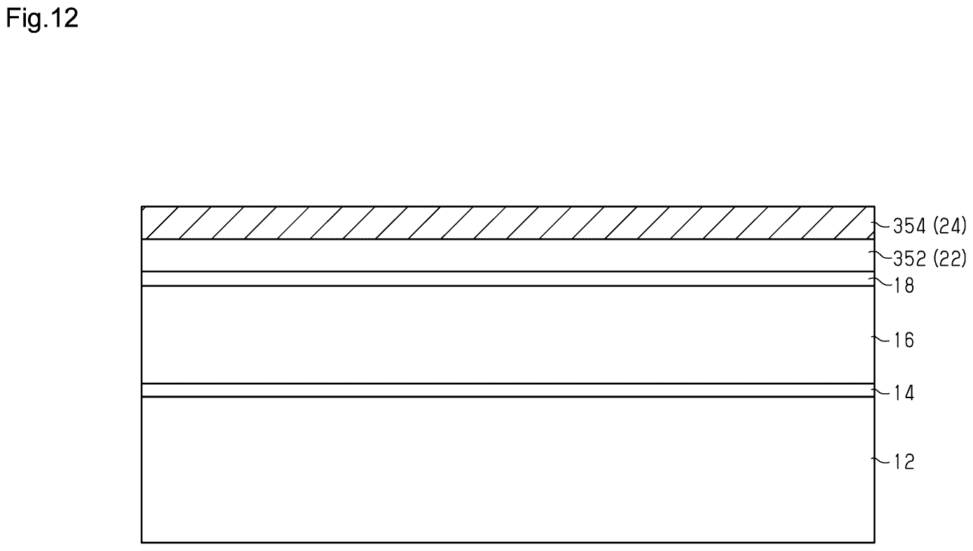

FIGS. 12 to 18 are schematic cross-sectional views showing exemplary manufacturing steps of the nitride semiconductor device 300. To facilitate understanding, in FIGS. 12 to 18, the same reference characters are given to those components that are the same as the corresponding components shown in FIG. 11. Elements that will ultimately become the elements of the nitride semiconductor device 300 are denoted by the corresponding reference characters shown in FIG. 11 in parentheses.

A method for manufacturing the nitride semiconductor device 300 includes forming the electron transit layer 16 composed of a nitride semiconductor, forming the electron supply layer 18 on the electron transit layer 16, the electron supply layer 18 being composed of a nitride semiconductor having a band gap that is larger than that of the electron transit layer 16, forming the gate layer 22 on the electron supply layer 18, the gate layer 22 composed of a nitride semiconductor including an acceptor impurity, forming the gate electrode 24 on the gate layer 22, and forming the insulation layer 302 (refer to FIG. 11) that covers the electron supply layer 18, the gate layer 22, and the gate electrode 24 and includes the first opening 302A and the second opening 302B.

In the present embodiment, the insulation layer 302 is the passivation layer 304 (refer to FIG. 11). Therefore, forming the insulation layer 302 includes forming the passivation layer 304 that covers the electron supply layer 18, the gate layer 22, and the gate electrode 24 and includes a first opening 304A and a second opening 304B. The first opening 304A and the second opening 304B of the passivation layer 304 respectively correspond to the first opening 302A and the second opening 302B of the insulation layer 302.

Forming the insulation layer 302 (the passivation layer 304) includes selectively etching the insulation layer 302 (the passivation layer 304) so that the first insulation layer part 302P1 differs in thickness from the second insulation layer part 302P2 (refer to FIG. 11).

As shown in FIG. 12, for example, the buffer layer 14, the electron transit layer 16, the electron supply layer 18, a nitride semiconductor layer 352, and a metal layer 354 are sequentially formed on the substrate 12, which is a Si substrate.

The buffer layer 14, the electron transit layer 16, the electron supply layer 18, and the nitride semiconductor layer 352 may be epitaxially grown by MOCVD.

Although not shown in detail, in an example, the buffer layer 14 is multilayer. An AlN layer (the first buffer layer) is formed on the substrate 12, and then a graded AlGaN layer (the second buffer layer) is formed on the AlN layer. The graded AlGaN layer is formed, for example, by stacking three AlGaN layers having Al compositions of 75%, 50%, and 25% in the order from the side of the AlN layer.

A GaN layer is formed on the buffer layer 14 as the electron transit layer 16. An AlGaN layer is formed on the electron transit layer 16 as the electron supply layer 18. Thus, the electron supply layer 18 has a band gap that is larger than that of the electron transit layer 16. Then, a GaN layer including an acceptor impurity is formed on the electron supply layer 18 as the nitride semiconductor layer 352.

The buffer layer 14, the electron transit layer 16, the electron supply layer 18, and the nitride semiconductor layer 352 are composed of nitride semiconductors having lattice constants relatively close to each other. This allows for sequential epitaxial growth of the layers.

Subsequently, the metal layer 354 is formed on the nitride semiconductor layer 352. In an example, the metal layer 354 is a TiN layer formed through sputtering.

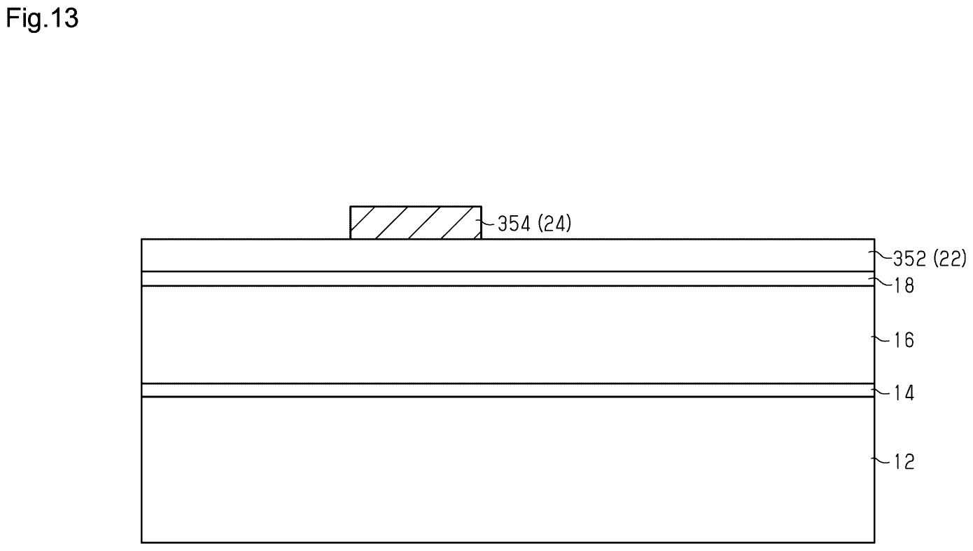

FIG. 13 is a schematic cross-sectional view showing a manufacturing step subsequent to FIG. 12. As shown in FIG. 13, the metal layer 354 is selectively removed by lithography and etching to form the gate electrode 24.

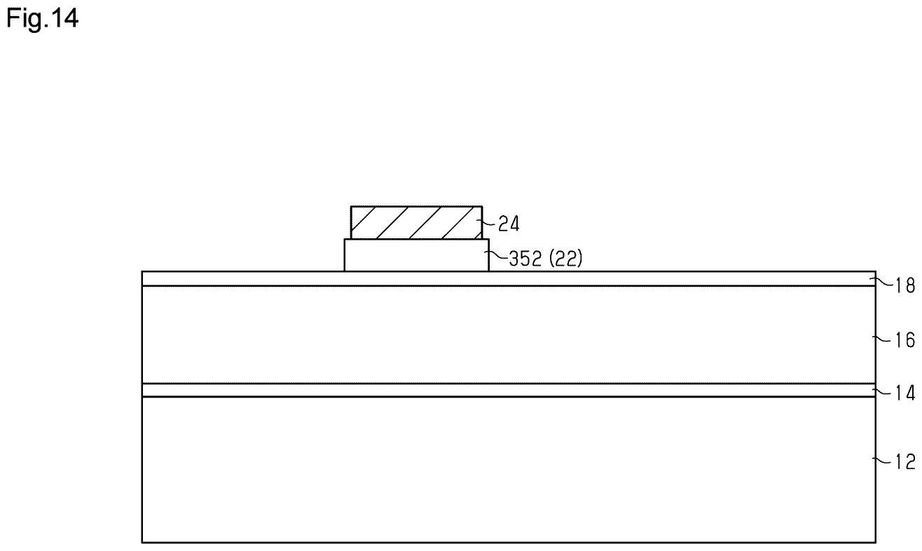

FIG. 14 is a schematic cross-sectional view showing a manufacturing step subsequent to FIG. 13. As shown in FIG. 14, the nitride semiconductor layer 352 is selectively removed by lithography and etching to form the gate layer 22. As a result, a stacked structure including the gate layer 22 and the gate electrode 24 formed on the gate layer 22 is formed on a portion of the upper surface of the electron supply layer 18.

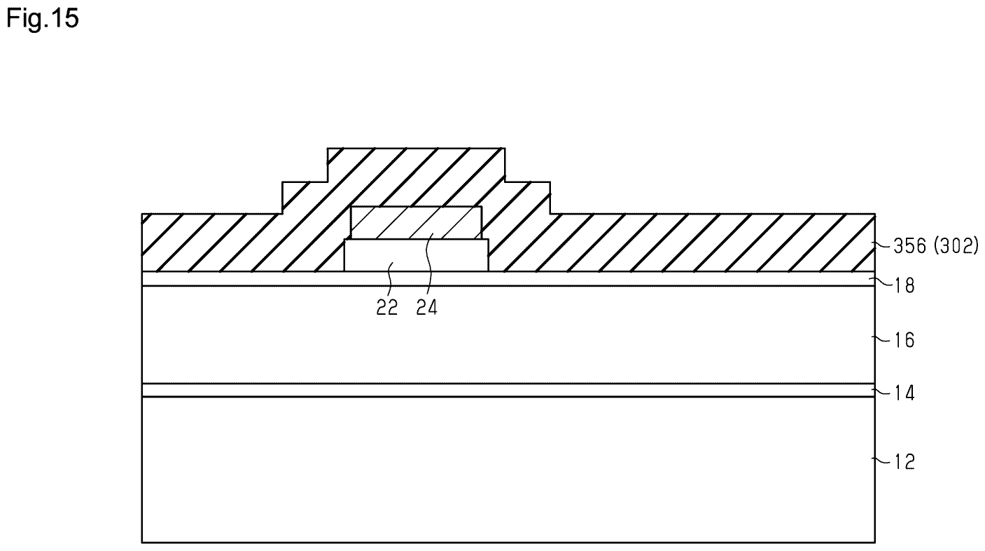

FIG. 15 is a schematic cross-sectional view showing a manufacturing step subsequent to FIG. 14. As shown in FIG. 15, a passivation insulation layer 356 is formed to cover the entirety of exposed surfaces of the electron supply layer 18, the gate layer 22, and the gate electrode 24. In an example, the passivation insulation layer 356 is a SiN layer formed by LPCVD. The passivation insulation layer 356 may have a thickness that is greater than or equal to 100 nm and less than or equal to 400 nm.

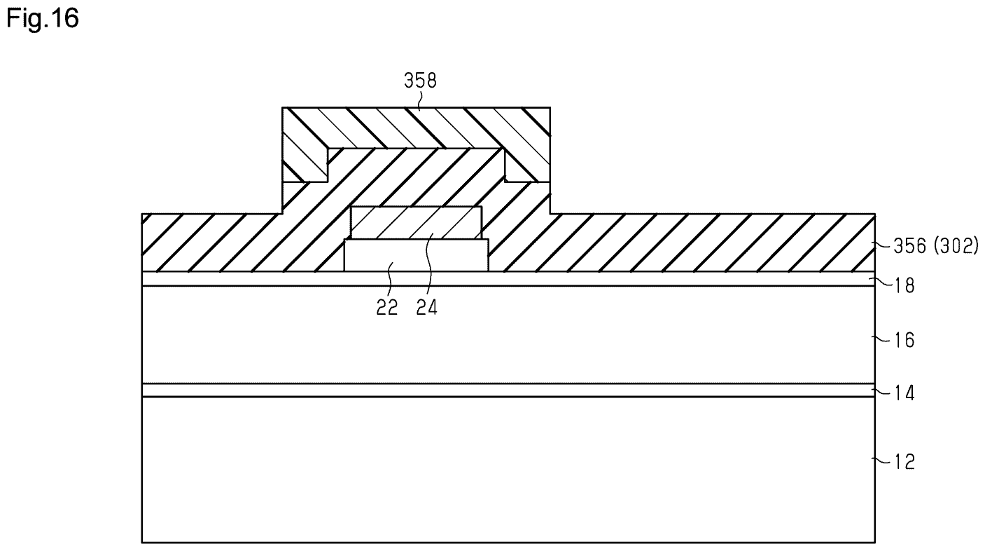

FIG. 16 is a schematic cross-sectional view showing a manufacturing step subsequent to FIG. 15. As shown in FIG. 16, a mask 358 (e.g., photoresist) is formed to cover a portion of the upper surface of the passivation insulation layer 356. In an example, a photoresist is applied to the entire surface of the passivation insulation layer 356, and exposure is performed to form the mask 358 on a portion of the upper surface of the passivation insulation layer 356.

The region in which the mask 358 is formed includes a formation region in which at least the gate layer 22 and the gate electrode 24 are formed in plan view. In plan view, the mask 358 is greater in size than the formation region and is formed in a region that does not cover the first opening 302A and the second opening 302B shown in FIG. 11.

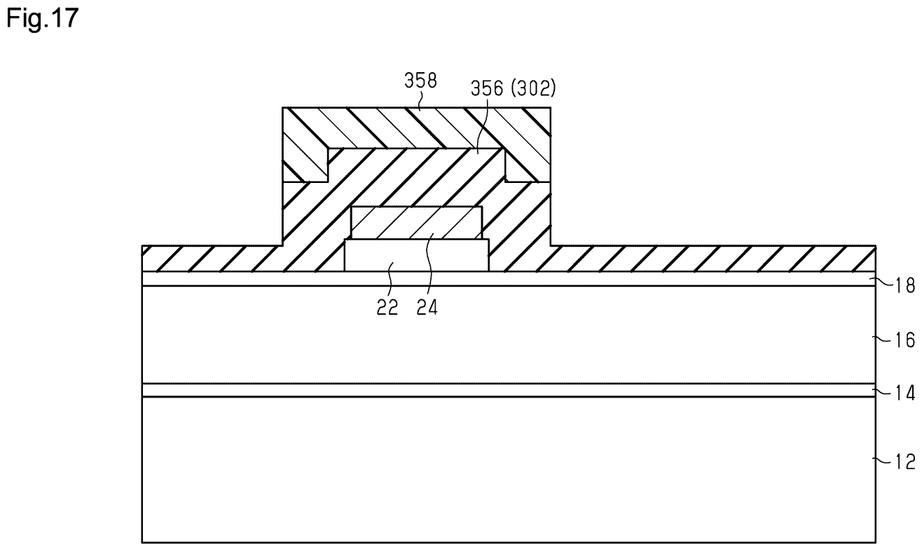

FIG. 17 is a schematic cross-sectional view showing a manufacturing step subsequent to FIG. 16. As shown in FIG. 17, the passivation insulation layer 356 is selectively etched using the mask 358. As a result, while the thickness of the passivation insulation layer 356 is maintained in a region covered by the mask 358, the thickness of the passivation insulation layer 356 is decreased in a region that is not covered by the mask 358. In the region that is not covered by the mask 358, after etching, the passivation insulation layer 356 may have a thickness that is greater than or equal to 50 nm and less than or equal to 200 nm. The mask 358 is removed after etching. Such selective etching of the passivation insulation layer 356 allows the first insulation layer part 302P1 and the second insulation layer part 302P2 to have different thicknesses in the resultant nitride semiconductor device 300.

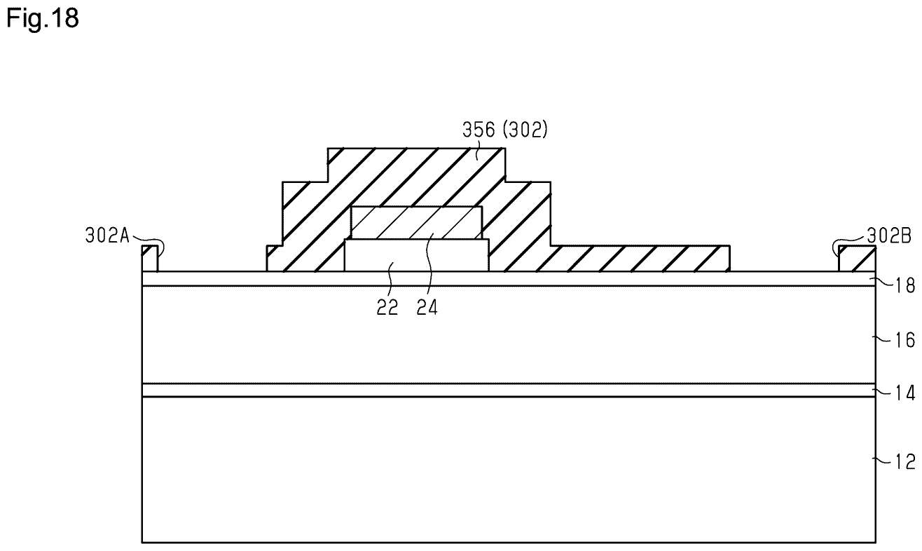

FIG. 18 is a schematic cross-sectional view showing a manufacturing step subsequent to FIG. 17. As shown in FIG. 18, the passivation insulation layer 356 is selectively removed by lithography and etching to form the insulation layer 302 including the first opening 302A and the second opening 302B. More specifically, the passivation insulation layer 356 is patterned so that the gate layer 22 is disposed between the first opening 302A and the second opening 302B. This forms the insulation layer 302 that covers the electron supply layer 18, the gate layer 22, and the gate electrode 24 and includes the first opening 302A and the second opening 302B.

The method for manufacturing the nitride semiconductor device 300 further includes forming the source electrode 28 (refer to FIG. 11), which is in contact with the electron supply layer 18 through the first opening 302A, and forming the drain electrode 30 (refer to FIG. 11), which is in contact with the electron supply layer 18 through the second opening 302B.

In a manufacturing step subsequent to the step shown in FIG. 18, a metal layer is formed to fill the first opening 302A and the second opening 302B and cover the entirety of exposed surfaces of the insulation layer 302. The metal layer (e.g., one or more metal layers including Ti, Al, TiN, and the like) is patterned by lithography and etching to form the source electrode 28 and the drain electrode 30. The source electrode 28 includes the source field plate 28B covering the insulation layer 302. The source field plate 28B includes the end 28C located between the second opening 302B and the gate layer 22 in plan view. This obtains the nitride semiconductor device 300 shown in FIG. 11.

The operation of the nitride semiconductor device 300 of the present embodiment will be described below.

In the nitride semiconductor device 300, the insulation layer 302 includes the first insulation layer part 302P1 having the first thickness D1 and the second insulation layer part 302P2 having the second thickness D2 that is greater than the first thickness D1. The second thickness D2 corresponds to the distance between the gate electrode 24 and the source electrode 28 in a region of the gate electrode 24 in plan view. In this structure, the distance between the gate electrode 24 and the source electrode 28 in the Z-direction is increased as compared to a structure in which the second thickness D2 is equal to the first thickness D1. Thus, the gate-source capacitance C_{gs} of the nitride semiconductor device 300 is decreased.

The operation characteristics of the nitride semiconductor device 300 may correspond to test example 1 shown in FIGS. 8 and 9 in the same manner as the nitride semiconductor device 10 of the first embodiment. Therefore, the increase in the second thickness D2 from the first thickness D1 decreases the gate-source capacitance C_{gs}, thereby decreasing the input capacitance Cᵢₛₛ and the total gate charge Q_{g}.

The nitride semiconductor device 300 of the third embodiment has the following advantages.
(3-1) The insulation layer 302 includes the first insulation layer part 302P1 having the first thickness D1 and the second insulation layer part 302P2 having the second thickness D2. The first insulation layer part 302P1 is disposed on the electron supply layer 18 in contact with the drain electrode 30. The second insulation layer part 302P2 is disposed on the gate electrode 24 in contact with the source field plate 28B. The second thickness D2 of the second insulation layer part 302P2 is greater than the first thickness D1 of the first insulation layer part 302P1.

In this structure, the distance between the gate electrode 24 and the source electrode 28 in the Z-direction is increased as compared to a structure in which the second thickness D2 is equal to the first thickness D1. This results in a decrease in the gate-source capacitance C_{gs}, thereby limiting an increase in the input capacitance Cᵢₛₛ and the total gate charge Q_{g}.
(3-2) The second thickness D2 is greater than or equal to 1.2 times the first thickness (D1) and less than or equal to 5.0 times the first thickness (D1).

In this structure, the gate-source capacitance C_{gs} is decreased by a relatively large amount. Thus, increases in the input capacitance Cᵢₛₛ and the total gate charge Q_{g}. are further effectively limited.

### Modified Examples

The embodiments described above may be modified as follows. The embodiments described above and the modified examples described below can be combined as long as the combined modifications remain technically consistent with each other.

In the first embodiment, from the viewpoint of decreasing the gate-source capacitance C_{gs}, the spacer layer 32 may be composed of a material having a lower electric permittivity than a material of the passivation layer 34.

In FIG. 1, the spacer layer 32 is formed on the entire upper surface 24B of the gate electrode 24. Instead, the spacer layer 32 may be formed on a portion of the upper surface 24B of the gate electrode 24. Alternatively, the spacer layer 32 may be formed on the upper surface 24B and the side surface 24C of the gate electrode 24.

In the embodiments, each of the passivation layer 34, the spacer layer 32, and the insulation layer 302 is composed of one of SiN, SiO₂, SiON, Al₂O₃, AlN, and AlON. Alternatively, each of the passivation layer 34, the spacer layer 32, and the insulation layer 302 may be a composite film including two or more of SiN, SiO₂, SiON, Al₂O₃, AlN, and AlON.

The gate electrode 24 may be formed on at least a portion of the gate layer 22. In an example, in the embodiments, the gate electrode 24 may be formed on the entire gate layer 22.

In this specification, “at least one of A and B” should be understood to mean “only A, or only B, or both A and B”.

In the present disclosure, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. In other words, the term “on” does not exclude a structure in which another layer is formed between the first layer and the second layer. For example, the above embodiment in which the electron supply layer 18 is formed on the electron transit layer 16 includes a structure in which an intermediate layer is disposed between the electron supply layer 18 and the electron transit layer 16 to stably form the 2DEG 20.

The Z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may conform to the vertical direction. The Y-axis direction may conform to the vertical direction.

### CLAUSES

The technical aspects that are understood from the embodiments and the modified examples will be described below. To facilitate understanding without intention to limit, the reference signs of the elements in the embodiments are given to the corresponding elements in the clause with parentheses. The reference signs used as examples to facilitate understanding, and the elements in each clause are not limited to those elements given with the reference signs.
A1. A nitride semiconductor device, including:
an electron transit layer (16) composed of a nitride semiconductor;
an electron supply layer (18) formed on the electron transit layer (16), the electron supply layer (18) being composed of a nitride semiconductor having a band gap that is larger than that of the electron transit layer (16);
a gate layer (22) formed on the electron supply layer (18), the gate layer (22) being composed of a nitride semiconductor including an acceptor impurity;
a gate electrode (24) formed on the gate layer (22);
an insulation layer (26) covering the electron supply layer (18), the gate layer (22), and the gate electrode (24) and including a first opening (26A) and a second opening (26B);
a source electrode (28) in contact with the electron supply layer (18) through the first opening (26A); and
a drain electrode (30) in contact with the electron supply layer (18) through the second opening (26B), where
the gate layer (22) is located between the first opening (26A) and the second opening (26B),
the source electrode (28) includes a source field plate (28B) covering the insulation layer (26), the source field plate (28B) includes an end (28C) located between the second opening (26B) and the gate layer (22) in plan view,
the insulation layer (26) includes
   a first insulation layer part (26P1) that is disposed on the electron supply layer (18) in contact with the drain electrode (30) and has a first thickness (D1), and
   a second insulation layer part (26P2) that is disposed on the gate electrode (24) in contact with the source field plate (28B) and has a second thickness (D2), the end (28C) of the source field plate (28B) is disposed on the first insulation layer part (26P1), and
the second thickness (D2) of the second insulation layer part (26P2) is greater than the first thickness (D1) of the first insulation layer part (26P1).
A2. The nitride semiconductor device according to clause A1, where the second thickness (D2) is greater than or equal to 1.2 times the first thickness (D1) and less than or equal to 5.0 times the first thickness (D1).
A3. The nitride semiconductor device according to clause A1 or A2, where
the first thickness (D1) is greater than or equal to 50 nm and less than or equal to 200 nm, and
the second thickness (D2) is greater than or equal to 100 nm and less than or equal to 400 nm.
A4. The nitride semiconductor device according to any one of clauses A1 to A3, in which
the insulation layer (26) includes
   a spacer layer (32) formed on the gate electrode (24), and
   a passivation layer (34) covering the electron supply layer (18), the gate layer (22), the gate electrode (24), and the spacer layer (32) and including the first opening (26A) and the second opening (26B),
the first insulation layer part (26P1) is formed of the passivation layer (34), and
the second insulation layer part (26P2) is formed of the spacer layer (32) and the passivation layer (34).
A5. The nitride semiconductor device according to clause A4, where
in the first insulation layer part (26P1), the passivation layer (34) has the first thickness (D1),
in the second insulation layer part (26P2), the spacer layer (32) has a third thickness (D3), and the passivation layer (34) has a fourth thickness (D4), and
the second thickness (D2) is a sum of the third thickness (D3) and the fourth thickness (D4).
A6. The nitride semiconductor device according to clause A5, where the first thickness (D1) is substantially equal to the fourth thickness (D4).
A7. The nitride semiconductor device according to any one of clauses A4 to A6, in which the spacer layer (32) is composed of any one of SiN, SiO₂, SiON, Al₂O₃, AlN, and AlON.
A8. The nitride semiconductor device according to any one of clauses A4 to A7, in which the spacer layer (32) and the passivation layer (34) are composed of a same material.
A9. The nitride semiconductor device according to any one of clauses A4 to A8, in which each of the spacer layer (32) and the passivation layer (34) is composed of SiN.
A10. The nitride semiconductor device according to any one of clauses A4 to A7, in which the spacer layer (32) is composed of a material having a lower electric permittivity than a material of the passivation layer (34).
A11. The nitride semiconductor device according to any one of clauses A4 to A10, in which
the gate electrode (24) includes a first surface (24A) in contact with the gate layer and a second surface (24B) opposite to the first surface (24A), and
the spacer layer (32) is formed on a portion of the second surface (24B) of the gate electrode (24).

Al₂. The nitride semiconductor device according to any one of clauses A4 to A10, in which
the gate electrode (24) includes a first surface (24A) in contact with the gate layer (22), a second surface (24B) opposite to the first surface (24A), and a third surface (24C) extending between the first surface (24A) and the second surface (24B), and
the spacer layer (32) is formed on the second surface (24B) and the third surface (24C) of the gate electrode (24).
A13. The nitride semiconductor device according to any one of clauses A1 to A3, in which
the insulation layer (302) is a passivation layer (304), and
each of the first insulation layer part (302P1) and the second insulation layer part (302P2) is formed of the passivation layer (304).
A14. The nitride semiconductor device according to any one of clauses A4 to A13, in which the passivation layer (34; 304) is formed of any one of SiN, SiO₂, SiON, Al₂O₃, AlN, and AlON.
A15. The nitride semiconductor device according to any one of clauses A1 to A14, in which
the first thickness (D1) is a thickness of the insulation layer (26) where the end (28C) of the source field plate (28B) is located in plan view, and
the second thickness (D2) is a distance between the gate electrode (24) and the source electrode (28) in a region of the gate electrode (24) in plan view.
B1. A method for manufacturing a nitride semiconductor device, the method including:
forming an electron transit layer (16) composed of a nitride semiconductor;
forming an electron supply layer (18) on the electron transit layer (16), the electron supply layer (18) being composed of a nitride semiconductor having a band gap that is larger than that of the electron transit layer (16);
forming a gate layer (22) on the electron supply layer (18), the gate layer (22) being composed of a nitride semiconductor including an acceptor impurity;
forming a gate electrode (24) on the gate layer (22);
forming an insulation layer (26) that covers the electron supply layer (18), the gate layer (22), and the gate electrode (24) and includes a first opening (26A) and a second opening (26B);
forming a source electrode (28) that is in contact with the electron supply layer (18) through the first opening (26A); and
forming a drain electrode (30) that is in contact with the electron supply layer (18) through the second opening (26B), where
the gate layer (22) is located between the first opening (26A) and the second opening (26B),
the source electrode (28) includes a source field plate (28B) covering the insulation layer (26), the source field plate (28B) includes an end (28C) located between
the second opening (26B) and the gate layer (22) in plan view,
the insulation layer (26) includes
   a first insulation layer part (26P1) that is disposed on the electron supply layer (18) in contact with the drain electrode (30) and has a first thickness (D1), and
   a second insulation layer part (26P2) that is disposed on the gate electrode (24) in contact with the source field plate (28B) and has a second thickness (D2),
the end (28C) of the source field plate (28B) is disposed on the first insulation layer part (26P1),
the second thickness (D2) of the second insulation layer part (26P2) is greater than the first thickness (D1) of the first insulation layer part (26P1).
B2. The method according to clause B1, where the second thickness (D2) is greater than or equal to 1.2 times the first thickness (D1) and less than or equal to 5.0 times the first thickness (D1).
B3. The method according to clause B1 or B2, where
the first thickness (D1) is greater than or equal to 50 nm and less than or equal to 200 nm, and
the second thickness (D2) is greater than or equal to 100 nm and less than or equal to 400 nm.
B4. The method according to any one of clauses B1 to B3, in which
the forming an insulation layer (26) includes
   forming a spacer layer (32) on the gate electrode (24), and
   forming a passivation layer (34) that covers the electron supply layer (18), the gate layer (22), the gate electrode (24), and the spacer layer (32) and includes the first opening (26A) and the second opening (26B),
the first insulation layer part (26P1) is formed of the passivation layer (34), and
the second insulation layer part (26P2) is formed of the spacer layer (32) and the passivation layer (34).
B5. The method according to clause B4, where
in the first insulation layer part (26P1), the passivation layer (34) has the first thickness (D1),
in the second insulation layer part (26P2), the spacer layer (32) has a third thickness (D3), and the passivation layer (34) has a fourth thickness (D4), and
the second thickness (D2) is a sum of the third thickness (D3) and the fourth thickness (D4).
B6. The method according to clause B5, where the first thickness (D1) is substantially equal to the fourth thickness (D4).
B7. The method according to any one of clauses B4 to B6, in which the spacer layer (32) is composed of any one of SiN, SiO₂, SiON, Al₂O₃, AlN, and AlON.
B8. The method according to any one of clauses B4 to B7, in which the spacer layer (32) and the passivation layer (34) are composed of a same material.
B9. The method according to any one of clauses B4 to B8, in which each of the spacer layer (32) and the passivation layer (34) is composed of SiN.
B10. The method according to any one of clauses B4 to B7, in which the spacer layer (32) is composed of a material having a lower electric permittivity than a material of the passivation layer (34).
B11. The method according to any one of clauses B4 to B10, in which
the gate electrode (24) includes a first surface (24A) in contact with the gate layer (22) and a second surface (24B) opposite to the first surface (24A), and
the spacer layer (32) is formed on a portion of the second surface (24B) of the gate electrode (24).
B12. The method according to any one of clauses B4 to B10, in which
the gate electrode (24) includes a first surface (24A) in contact with the gate layer (22), a second surface (24B) opposite to the first surface (24A), and a third surface (24C) extending between the first surface (24A) and the second surface (24B), and
the spacer layer (32) is formed on the second surface (24B) and the third surface (24C) of the gate electrode (24).
B13. The method according to any one of clauses B1 to B3, in which
the forming an insulation layer (302) includes forming a passivation layer (304) that covers the electron supply layer (18), the gate layer (22), and the gate electrode (24) and includes the first opening (304A) and the second opening (304B), and
each of the first insulation layer part (302P1) and the second insulation layer part (302P2) is formed of the passivation layer (304).
B14. The method according to any one of clauses B4 to B13, in which the passivation layer (34; 302) is formed of any one of SiN, SiO₂, SiON, Al₂O₃, AlN, and AlON.
B15. The method according to any one of clauses B1 to B14, in which
the first thickness (D1) is a thickness of the insulation layer (26) where the end (28C) of the source field plate (28B) is located in plan view, and
the second thickness (D2) is a distance between the gate electrode (24) and the source electrode (28) in a region of the gate electrode (24) in plan view.
B16. The method according to any one of clauses B13 to B15, in which the forming a passivation layer (304) includes selectively etching the passivation layer (304) so that the first insulation layer part (302P1) differs in thickness from the second insulation layer part (302P2).
B17. The method according to any one of clauses B1 to B3, in which the forming an insulation layer (302) includes selectively etching the insulation layer (302) so that the first insulation layer part (302P1) differs in thickness from the second insulation layer part (302P2).

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
an electron transit layer composed of a nitride semiconductor;
an electron supply layer formed on the electron transit layer, the electron supply layer being composed of a nitride semiconductor having a band gap that is larger than that of the electron transit layer;
a gate layer formed on the electron supply layer, the gate layer being composed of a nitride semiconductor including an acceptor impurity;
a gate electrode formed on the gate layer;
an insulation layer covering the electron supply layer, the gate layer, and the gate electrode and including a first opening and a second opening;
a source electrode in contact with the electron supply layer through the first opening; and
a drain electrode in contact with the electron supply layer through the second opening, wherein
the gate layer is located between the first opening and the second opening,
the source electrode includes a source field plate covering the insulation layer,
the source field plate includes an end located between the second opening and the gate layer in plan view,
the insulation layer includes
a first insulation layer part that is disposed on the electron supply layer in contact with the drain electrode and has a first thickness, and
a second insulation layer part that is disposed on the gate electrode in contact with the source field plate and has a second thickness,
the end of the source field plate is disposed on the first insulation layer part, and
the second thickness of the second insulation layer part is greater than the first thickness of the first insulation layer part.

2. The nitride semiconductor device according to claim 1, wherein the second thickness is greater than or equal to 1.2 times the first thickness and less than or equal to 5.0 times the first thickness.

3. The nitride semiconductor device according to claim 1, wherein
the first thickness is greater than or equal to 50 nm and less than or equal to 200 nm, and
the second thickness is greater than or equal to 100 nm and less than or equal to 400 nm.

4. The nitride semiconductor device according to claim 1, wherein
the insulation layer includes
a spacer layer formed on the gate electrode, and
a passivation layer covering the electron supply layer, the gate layer, the gate electrode, and the spacer layer and including the first opening and the second opening,
the first insulation layer part is formed of the passivation layer, and
the second insulation layer part is formed of the spacer layer and the passivation layer.

5. The nitride semiconductor device according to claim 4, wherein
in the first insulation layer part, the passivation layer has the first thickness,
in the second insulation layer part, the spacer layer has a third thickness, and the passivation layer has a fourth thickness, and
the second thickness is a sum of the third thickness and the fourth thickness.

6. The nitride semiconductor device according to claim 5, wherein the first thickness is substantially equal to the fourth thickness.

7. The nitride semiconductor device according to claim 4, wherein the spacer layer is composed of any one of SiN, SiO₂, SiON, Al₂O₃, AlN, and AlON.

8. The nitride semiconductor device according to claim 4, wherein the spacer layer and the passivation layer are composed of a same material.

9. The nitride semiconductor device according to claim 4, wherein each of the spacer layer and the passivation layer is composed of SiN.

10. The nitride semiconductor device according to claim 4, wherein the spacer layer is composed of a material having a lower electric permittivity than a material of the passivation layer.

11. The nitride semiconductor device according to claim 4, wherein
the gate electrode includes a first surface in contact with the gate layer and a second surface opposite to the first surface, and
the spacer layer is formed on a portion of the second surface of the gate electrode.

12. The nitride semiconductor device according to claim 4, wherein
the gate electrode includes a first surface in contact with the gate layer, a second surface opposite to the first surface, and a third surface extending between the first surface and the second surface, and
the spacer layer is formed on the second surface and the third surface of the gate electrode.

13. The nitride semiconductor device according to claim 1, wherein
the insulation layer is a passivation layer, and
each of the first insulation layer part and the second insulation layer part is formed of the passivation layer.

14. The nitride semiconductor device according to claim 4, wherein the passivation layer is composed of any one of SiN, SiO₂, SiON, Al₂O₃, AlN, and AlON.

15. The nitride semiconductor device according to claim 1, wherein
the first thickness is a thickness of the insulation layer where the end of the source field plate is located in plan view, and
the second thickness is a distance between the gate electrode and the source electrode in a region of the gate electrode in plan view.

16. A method for manufacturing a nitride semiconductor device, the method comprising:
forming an electron transit layer composed of a nitride semiconductor;
forming an electron supply layer on the electron transit layer, the electron supply layer being composed of a nitride semiconductor having a band gap that is larger than that of the electron transit layer;
forming a gate layer on the electron supply layer, the gate layer being composed of a nitride semiconductor including an acceptor impurity;
forming a gate electrode on the gate layer;
forming an insulation layer that covers the electron supply layer, the gate layer, and the gate electrode and includes a first opening and a second opening;
forming a source electrode that is in contact with the electron supply layer through the first opening; and
forming a drain electrode that is in contact with the electron supply layer through the second opening, wherein
the gate layer is located between the first opening and the second opening,
the source electrode includes a source field plate covering the insulation layer,
the source field plate includes an end located between the second opening and the gate layer in plan view,
the insulation layer includes
a first insulation layer part that is disposed on the electron supply layer in contact with the drain electrode and has a first thickness, and
a second insulation layer part that is disposed on the gate electrode in contact with the source field plate and has a second thickness,
the end of the source field plate is disposed on the first insulation layer part, and
the second thickness of the second insulation layer part is greater than the first thickness of the first insulation layer part.

17. The method according to claim 16, wherein the second thickness is greater than or equal to 1.2 times the first thickness and less than or equal to 5.0 times the first thickness.

18. The method according to claim 16, wherein
the first thickness is greater than or equal to 50 nm and less than or equal to 200 nm, and
the second thickness is greater than or equal to 100 nm and less than or equal to 400 nm.

19. The method according to claim 16, wherein
the forming an insulation layer includes
forming a spacer layer on the gate electrode, and
forming a passivation layer that covers the electron supply layer, the gate layer, the gate electrode, and the spacer layer and includes the first opening and the second opening,
the first insulation layer part is formed of the passivation layer, and
the second insulation layer part is formed of the spacer layer and the passivation layer.

20. The method according to claim 16, wherein the forming an insulation layer includes selectively etching the insulation layer so that the first insulation layer part differs in thickness from the second insulation layer part.
